(19) United States
(12) Patent Application Publication
(10) Pub. No.: US 2007/0285906 A1
(43) Pub. Date: Dec. 13, 2007

(54) VOLTAGE REGULATOR AND METHOD USING SUBSTRATE BOARD WITH INSULATOR LAYER AND CONDUCTIVE TRACES

(75) Inventors: Mike DEVERALL, Apopka, FL (US); Gary MORRISSETTE, Groveland, FL (US); Reginald L. BROWNING, Orlando, FL (US)

Correspondence Address: RICHARD K. WARTHER, ESQUIRE;ALLEN, DYER, DOPPELT, MILBRATH & GILCHRIST, P.A., P.O. Box 3791, Orlando, FL, 32802-3791, US

(73) Assignee: WETHERILL ASSOCIATES, INC., Royersford, PA (US)

(21) Appl. No.: 11/842,190

(22) Filed: Aug. 21, 2007

Related U.S. Application Data
(62) Division of application No. 10/982,176, filed on Nov. 5, 2004.

(51) Int. Cl. H05K 7/00

(52) U.S. Cl. 361/760

(57) ABSTRACT

A voltage regulator includes a voltage regulator body and connectors carried by the body, which connect to devices controlled by the voltage regulator. A substrate board is received in a board receiving cavity of the voltage regulator body and includes a metallic base layer, an insulator layer on the metallic base layer, and a circuit layer on the insulator layer and defining a printed circuit pattern. Active and passive voltage regulator components are mounted on the substrate board and interconnected by the printed circuit pattern to form a voltage regulating circuit. Terminal connections, such as conductive pins, are secured to the substrate board and operatively connected to selected active and passive components or printed circuit pattern and extend from the substrate board for interconnecting the connectors carried by the voltage regulator body.

### FIELD OF THE INVENTION

The present invention relates to voltage regulators, and more particularly, the present invention relates to voltage regulators for controlling voltage and current supplied from a generator or alternator used in maritime, automobile or motorcycle charging systems.

### BACKGROUND OF THE INVENTION

The charging system for an automobile, truck, motorcycle or boat typically includes an alternator or generator with appropriate windings, armature and stator components. A voltage regulator regulates the charging voltage and output current to provide consistent alternator or generator operation during varying loads that would create voltage drops and other operational problems. Many different regulator designs are commercially available, including discrete transistor, custom integrated circuit systems using Application Specific Integrated Circuits (ASIC), or hard-wired circuits that define a specific function for a specific type of application. These voltage regulators typically require the use of a heat sink for drawing heat away from the active and passive voltage regulator components, which are typically mounted on a conventional printed circuit board (PCB) or printed wiring board (PWB). The heat sink radiates excessive heat generated because of the voltage regulator operation into the atmosphere or mounting system.

This unwanted heat is generated at an integrated circuit (IC) junction or by other active components forming the voltage regulator circuit. When not carried away properly, this generated heat can impair or destroy the voltage regulator. In some cases, the heat can be so excessive, fires are started because of the proximity of the voltage regulator to a carburetor, fuel line, or other flammable substance or device. This problem is more problematic in those instances when space is minimal, and many vehicle components, including the engine, charging system, fuel delivery system and other components and associated vehicle systems are arranged in close proximity to each other.

Also, designed performance specifications for most commercially available voltage regulators assume the use of proper heat sinking. To ensure proper heat flow from the voltage regulator into a heat sink, it is sometimes possible to lower ambient temperature using ventilation, including a fan or other cooling technique. This adds cost and noise to a design and may not be in the original design specifications. It is also possible to lower the ambient heat by lowering the system operating power, but this is not always an adequate option because at peak load requirements, the voltage regulator will not adequately regulate voltage and/or current. It is also possible to choose higher current rated active and passive components, including any integrated circuits. This also adds cost and often requires a larger volume voltage regulator, which is not an acceptable design choice in some instances. Typical commercial heat sinks include Thermalloy, Wakefield, IERC, Staver, TO-204AA, TO-204AB, TO-226AA and similar commercially available heat sinks that have been applied to voltage regulator designs.

There are believed to have been some prior art proposals, for example, a voltage regulator sold by Unit Parts of Oklahoma City, Okla., for CS130 alternators, which uses a substrate board having conductive traces forming a printed circuit pattern, an insulator layer and a copper base layer operative as the heat sink. A lead frame assembly formed in the voltage regulator body includes interior terminals attached directly to the substrate board to connect components or the circuit pattern on the circuit board. This structure has not been found adequate because the direct connection of lead frame components is expensive to tool for automation, difficult to manufacture, and requires high tolerance.

### SUMMARY OF THE INVENTION

It is therefore an object of the present invention to provide a voltage regulator that has lower operating temperatures, longer operating life, and is more durable and robust than prior art voltage regulators that use standard printed wiring (or circuit) boards or thick-film ceramics.

It is another object of the present invention to provide a voltage regulator that does not require the use of a large heat sink.

It is yet another object of the present invention to provide a voltage regulator that has a reduced board size, increased power density, lower operating temperature, and a reduced number of interconnects.

It is still another object of the present invention to provide a voltage regulator that uses surface mount technology.

The present invention is directed to a voltage regulator that controls voltage and current supplied from a generator or alternator, and includes a substrate board received on a voltage regulator body. The substrate board minimizes thermal impedance and conducts heat more efficiently and effectively than standard printed wiring boards and is more mechanically robust than thick-film ceramics and direct bond copper constructions often used in prior art voltage regulators.

The substrate board is received on the voltage regulator body and is formed as a metallic base layer, an insulator layer on the metallic base layer, and a circuit layer on the insulator layer and defining a printed circuit pattern. Active and passive voltage regulator components are mounted on the substrate board and interconnected by the printed circuit pattern to form a voltage regulating circuit. Connectors are carried by the voltage regulator body and adapted to be connected to devices controlled by the voltage regulator, including other components of the vehicle. Terminal connections are secured to the substrate board and operatively connected to selected active and passive components or printed circuit pattern and extend from the substrate board and interconnect the connectors carried by the voltage regulator body.

The voltage regulator body includes a board receiving cavity into which the substrate board is received. An insulator material typically fills the board receiving cavity and covers the substrate board and active and passive voltage regulator components. The voltage regulator body can also include a metallic surface on which the metallic base of the substrate board is secured.

In yet another aspect of the present invention, wire terminals are carried by the voltage regulator body and connected to the terminal connections and form a wiring harness. The voltage regulator body could be formed as an integrally formed metallic housing, or the voltage regulator could include a lead frame assembly formed of an insulator material with conductors embedded within the lead frame assembly and connected to the terminal connections. In this aspect of the invention, the terminal connections could be conductor pins that connect to internal terminals of the embedded conductors.

In yet another aspect of the present invention, the voltage regulator body is formed as an integrally formed, one-piece metallic housing, which can be configured for mounting on a powered vehicle, including a boat, automobile or motorcycle. The active and passive regulator components can be surface mounted components and adhered to the substrate board by reflow soldering.

The metallic base layer of the conductive substrate is typically formed from copper or aluminum, and in one aspect of the present invention, is preferably formed from aluminum. Solder connections secure at least a portion of the active and passive voltage regulator components on the circuit layer. The coefficient of thermal expansion for the aluminum base layer minimizes solder joint fatigue and enhances heat spreading. This aluminum base layer can have a thickness of about 0.020 to about 0.125 inches, in one non-limiting example.

The voltage regulator can be adapted for use in marine engine system applications, motorcycle system applications, A-circuit (low-side) vehicle system applications, B-circuit (high-side) vehicle system applications, and permanent magnet applications, as non-limiting examples. The same manufacturing techniques could even be applied to an ignition module used on magnetic pick-up vehicle system applications. A method of forming a voltage regulator in accordance with the present invention is also disclosed.

### BRIEF DESCRIPTION OF THE DRAWINGS

Other objects, features and advantages of the present invention will become apparent from the detailed description of the invention which follows, when considered in light of the accompanying drawings in which:

FIG. 1 is an exploded isometric view of a voltage regulator used in marine applications and including an integrally formed metallic housing and showing the substrate board received within the housing, and wires to be carried by the housing for connecting to terminal connections as conductor pins extending from the substrate board.

FIG. 2 is an isometric view of the voltage regulator of FIG. 1 showing the substrate board received in the housing and wire terminals soldered to the conductive pins.

FIG. 3 is a top plan view of the voltage regulator shown in FIG. 2 and showing in detail a wire terminal connected to a conductive pin.

FIG. 4 is an isometric view of the voltage regulator similar to the view shown in FIG. 2, but showing an insulator material filling the board receiving cavity of the housing and covering the substrate board and active and passive components.

FIGS. 4A-4D are plan views of other embodiments of the voltage regulator shown in FIGS. 1-4 and used typically in marine applications, but showing different plug configurations.

FIG. 5 is a sectional view of one example of the substrate board of the present invention.

FIG. 6 is a top plan view of the substrate board shown in FIGS. 1-3 and showing the printed circuit pattern and interconnected active and passive components.

FIG. 7 is an enlarged, isometric view of the substrate board shown in FIG. 6 and showing in greater detail various active and passive components that are surface mounted and secured by soldering.

FIG. 8 is an exploded isometric view of another example of a voltage regulator of the present invention used in CS130 series and similar alternators and showing the substrate board, board receiving cavity, and cover.

FIG. 9 is an isometric view of the voltage regulator shown in FIG. 8 and showing the substrate board received within the board receiving cavity.

FIG. 10 is an enlarged isometric view of a portion of the voltage regulator of FIG. 9 and showing the substrate board received in the board receiving cavity and conductive pins that are bent and connected to internal terminals of the lead frame assembly.

FIG. 11 is another example of a voltage regulator of the present invention for an A-circuit (low-side) voltage regulation system showing the relation of the substrate board to the board receiving cavity in the lead frame assembly.

FIG. 12 is a top plan view of the voltage regulator shown in FIG. 11.

FIG. 13 is another isometric view of the voltage regulator shown in FIG. 11 and showing the position where a filler is inserted between the substrate board and lead frame assembly forming a brush housing.

FIG. 14 is a top plan view of the substrate board and showing an example of a circuit layout for different active and passive components.

FIG. 15 is an exploded isometric view of an example of an ignition module used for a magnetic pick-up ignition system and showing the relationship of the substrate board relative to a board receiving cavity formed in a lead frame assembly.

FIG. 16 is another example of a voltage regulator of the present invention used on motorcycles, and showing the relationship of the substrate board to the integrally formed housing and its board receiving cavity.

FIG. 17 is an isometric view of the voltage regulator shown in FIG. 16 with the substrate board received within the board receiving cavity.

FIG. 18 is an exploded isometric view of another example of a voltage regulator used in permanent magnet applications and showing the relation of the substrate board relative to the board receiving cavity of a housing.

FIG. 19 is an isometric view of the voltage regulator shown in FIG. 18 with the substrate board received within the board receiving cavity.

FIG. 20 is an isometric view of a voltage regulator shown in FIGS. 18 and 19, and showing wires carried by the housing and forming a wiring harness, and an insulator material filling the board receiving cavity and covering the substrate board and active and passive voltage regulator components.

### DETAILED DESCRIPTION OF THE PREFERRED EMBODIMENTS

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout, and prime notation is used to indicate similar elements in alternative embodiments.

The present invention advantageously provides a voltage regulator that overcomes the disadvantages of prior art voltage regulators that require large heat sinks to withdraw heat from the voltage regulation circuit, which controls voltage and current supplied from a generator or alternator in different vehicle applications, including automobile, motorcycle and marine systems. In accordance with the present invention, a substrate board is received on a voltage regulator body, for example, formed as a metallic housing or lead frame assembly.

This substrate board could be referred to as an insulated and conductive board because it includes a metallic base layer, such as formed from copper or aluminum, an insulator layer on the metallic base layer, and a circuit layer on the insulator layer and defining a printed circuit pattern. Active and passive voltage regulator components, such as transistors, resistors, capacitors, diodes and similar voltage regulator components, are mounted on the substrate board and interconnected by the printed circuit pattern to form a voltage regulating circuit. Terminal connections, for example, conductive pins, are secured to the substrate board and operatively connected to selected active and passive components and extend from the substrate board and interconnect connectors that are carried by the voltage regulator body. These connectors carried by the voltage regulator body could be conductors embedded in a lead frame assembly.

The use of the substrate board allows the active and passive components to be surface mounted on the substrate board use reflow soldering in an efficient manner. The use of the substrate board also minimizes thermal impedance and conducts heat more effectively and efficiently than conventional printed circuit (or wiring) boards. This substrate board is stronger than typical thick-film ceramics or direct bond copper construction systems, and does not require a large heat sink or heat interface material using clamps, brackets, fastening screws, or other mounting hardware typically associated with prior art heat sinks used in voltage regulators.

The use of the substrate board also reduces overall operating temperature, and can extend the life of active and passive components, including any semiconductor dies mounted on the board. Surface mount technology, including reflow soldering, is preferably used, thus, reducing the number of interconnects and improving thermal and mechanical performance.

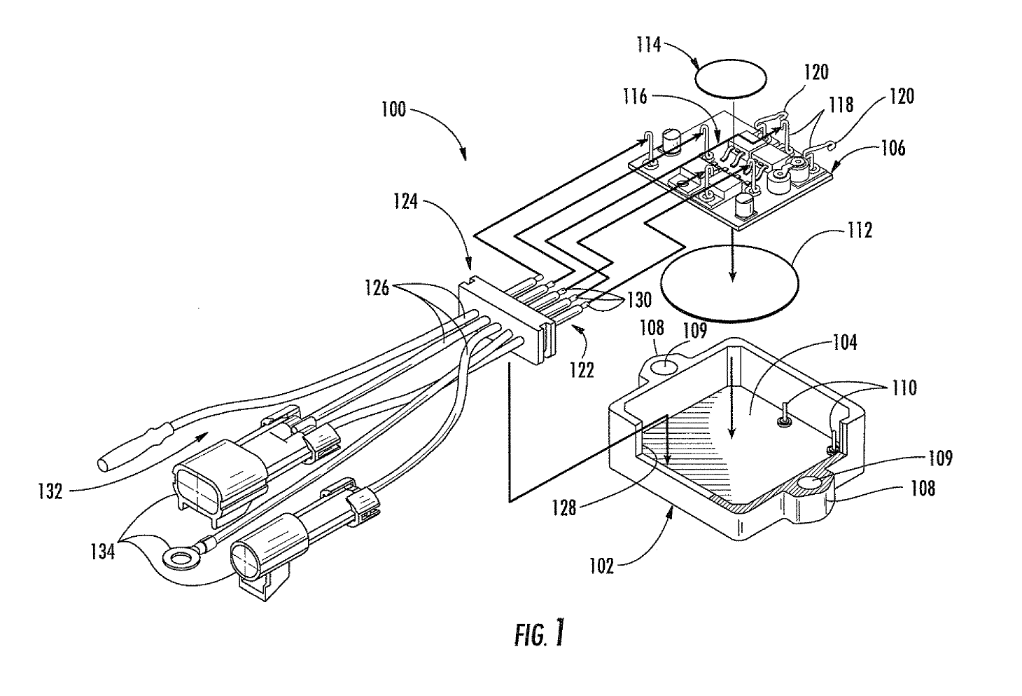

Referring now to FIG. 1, an exploded isometric view of a first embodiment of a voltage regulator 100 of the present invention is illustrated. This voltage regulator 100 can be used in marine applications, for example, Mercury-Marine engine applications. In this particular embodiment, a voltage regulator body 102 is cast as an integrally formed, metallic housing forming a “can” as referred to by those skilled in the art. The housing 102 includes a board receiving cavity 104 that receives the substrate board 106 of the present invention. The substrate board 106 is dimensioned to fit within the board receiving cavity 104 forming the “can.” The housing 102 in this particular embodiment is rectangular configured with opposing integrally formed fastener receiving protrusions 108 positioned on opposite sides. Bolts or other fasteners are received within holes 109 in the protrusions 108. Each hole 109 receives the fastener, such as a bolt, to secure the voltage regulator 100 inside an outboard engine or within a boat at a selected location. Two ground pins 110 are secured within the bottom of the board receiving cavity 104 and connect to terminal connections extending from the board as explained below.

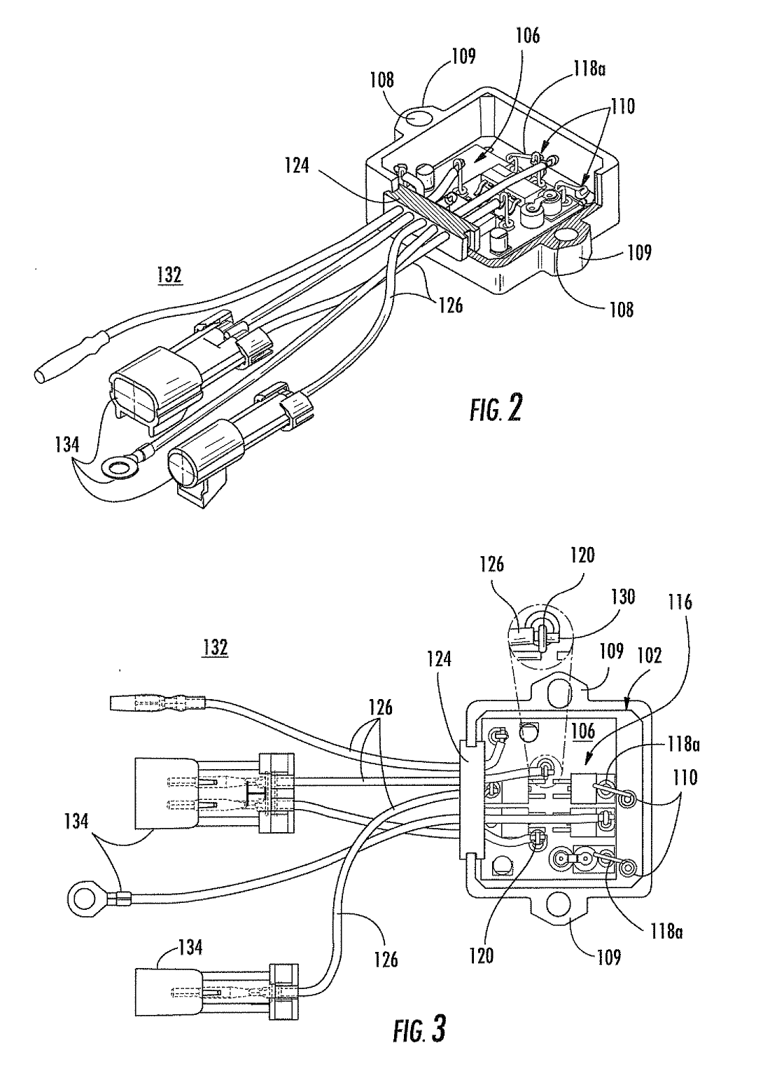

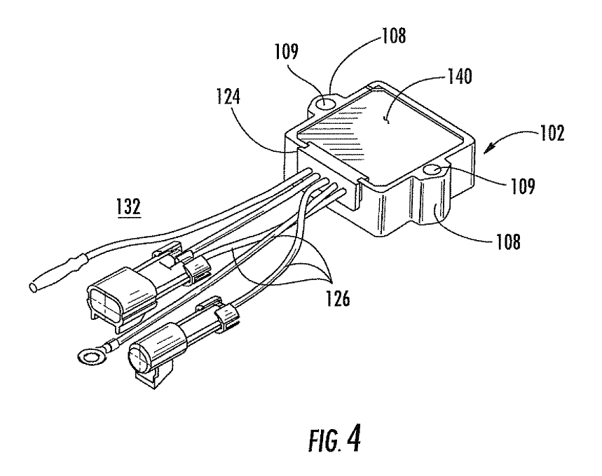

As illustrated, the substrate board 106 is adhered by an adhesive 112, for example, a conductive epoxy into the board receiving cavity 104. An example of such adhesive is an RTV, gray/white, SYLGARD, Q3-6605 adhesive. A conformal coating 114 can be applied over the substrate board 106 and active and passive electronic components 116 that are surface mounted, such as by reflow soldering onto the substrate board. FIG. 1 shows the different active and passive components 116 and terminal connections 118 formed as conductive pins that are secured to the substrate board and operatively connected to the selected active and passive components. These terminal connections 118 are preferably formed as extended, thick wires forming conductive pins, and include at their end J-hook connections 120 that engage connectors 122 carried by the voltage regulator housing 102. As illustrated, a grommet assembly 124 firmly holds individual wires 126 forming the connectors 122. The grommet assembly 124 is received in a grommet receiving slot 128 of the voltage regulator housing. Different wires 126 are carried by the voltage regulator housing and secured by the grommet assembly 124. Each wire 126 includes a stripped end or terminal end 130 that connects to the different terminal connections, as shown in FIGS. 1, 2 and 3, showing the terminal ends 130 of the wires 126 soldered to the J-hook connections 120 of the terminal connections or conductive pins 118. Although the specific design of any terminal connections 118 can vary, they typically would include any necessary stator, field, ground, sense, ignition, light, or battery (B+) connections from the substrate board and interconnecting to appropriate active and passive components and any circuit pattern for interconnection. The wires 126 extending from the grommet assembly 124 form parts of a wiring harness 132 and have different electrical couplers 134 that connect to different regulator controlled devices or control systems.

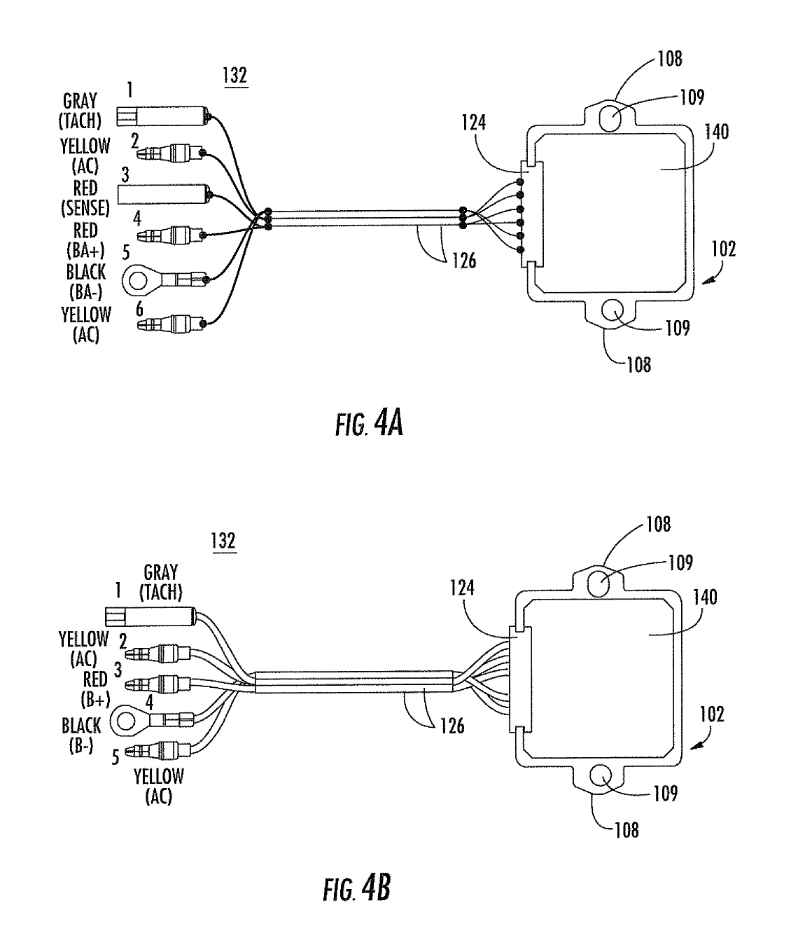

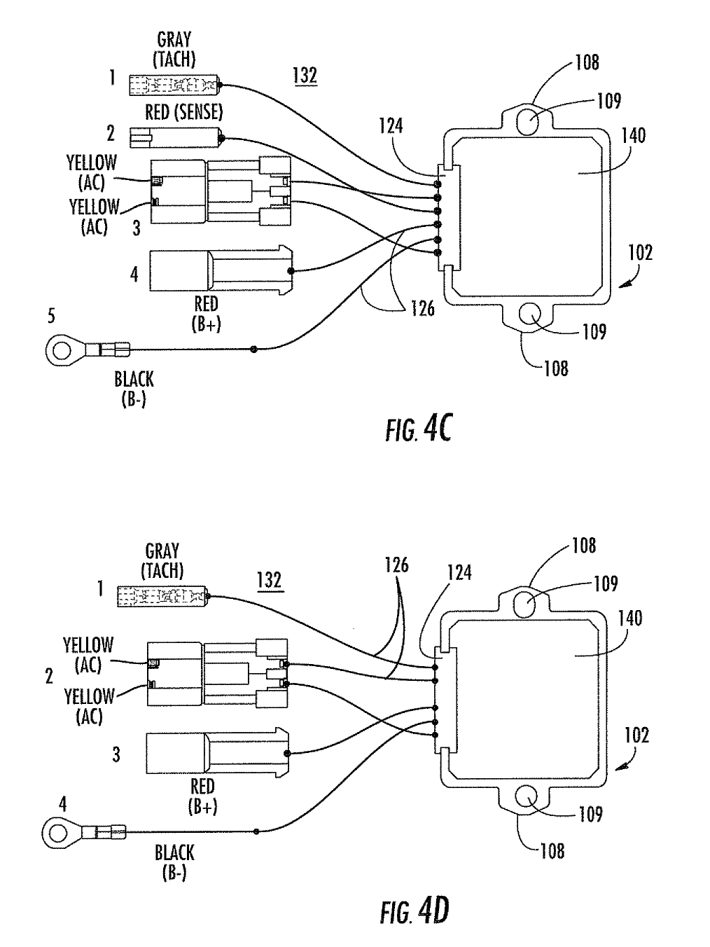

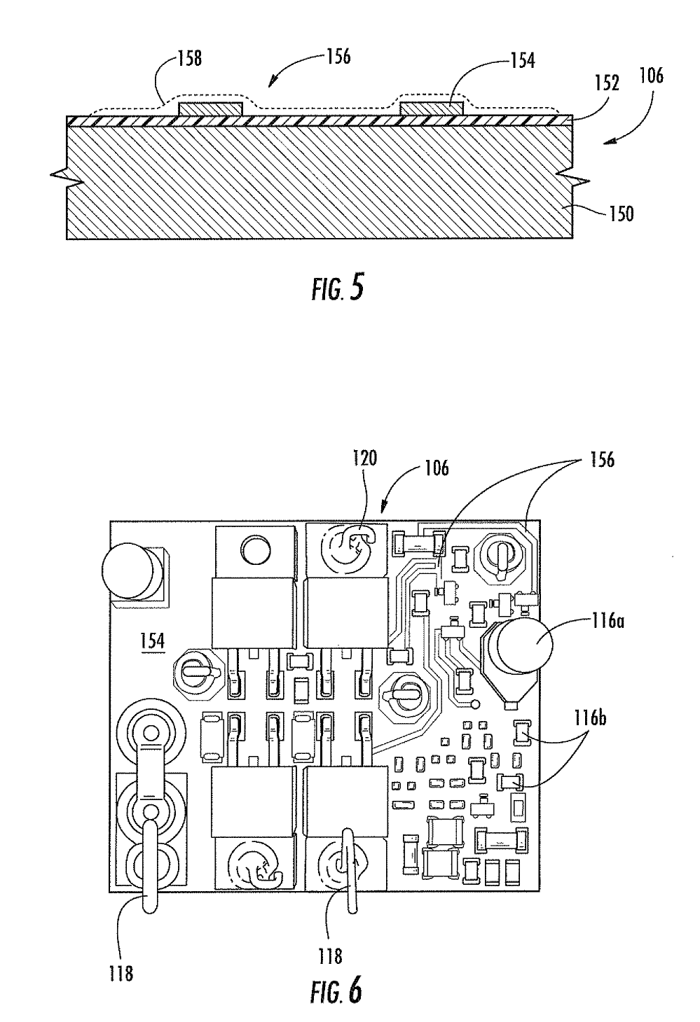

FIG. 4 shows an insulator material 140 that fills the board receiving cavity and covering the substrate board and active and passive voltage regulator components. This insulator material 140 can be formed as a urethane encapsulant base that includes a urethane activator.

The assembly process for the voltage regulator illustrated in FIGS. 1-4 can vary, but typically a glue such as the conductive epoxy 112 is dispensed onto the bottom of the substrate board 106. The substrate board 106 is inserted into the board receiving cavity 104 and, in one process example, heat cured at 100° C. for 30 minutes. The stripped end of the wires 126 forming terminal ends 130 are inserted into the J-hook connections 120 of the conductive pins 118. The J-hook connections 120 are crimped over the terminal ends 130 and soldered. The grommet assembly 124 is placed into the receiving slot 128 and pushed into place. The two ground pins 110 shown in FIG. 1 engage terminal connections as conductive pins 118 and a J-hook connection 120.

The substrate board and its active and passive components are covered completely with the conformal coating 114 and cured at room temperature for 15 minutes. It is possible to inspect with a UV inspection light and further curing can occur at 80° C. for 15 minutes.

As shown in FIG. 4, the insulator material, for example, a voltage encapsulant base 140 with urethane activator, acts as an adhesive and fills the board receiving cavity forming the “can” as shown in FIG. 4.

FIGS. 4A-4B are other embodiments of the voltage regulator shown in FIGS. 1-4 as used for marine applications, but showing different plug configurations.

FIG. 4A shows six separate plug terminals numbered 1-6. Terminal 1 could have a gray lead wire and be connected to the tachometer connection. Terminal 2 could have a yellow lead wire and be connected to the AC connection. Terminal 3 could have a red lead wire and be connected to the sense terminal. Terminal 4 could have a red lead wire and be connected to the battery positive terminal. Terminal 5 could have a black lead and be connected to the negative battery terminal. Terminal 6 could have a yellow lead and be connected to an AC terminal. The cable could be single conductor, stranded copper insulation type GXL temperature rating 125° C. AWG 16 size has been found acceptable. The various terminals are illustrated as male and female bullets and terminal ring, plug and receptacle.

FIG. 4B shows five terminals numbered 1-5 with respective tachometer, AC, positive battery, negative battery and AC connector.

FIG. 4C shows five terminals with a larger third terminal that has two internal terminal connections for the AC. FIG. ED is similar to FIG. 4C except there is no sense terminal with a red lead wire.

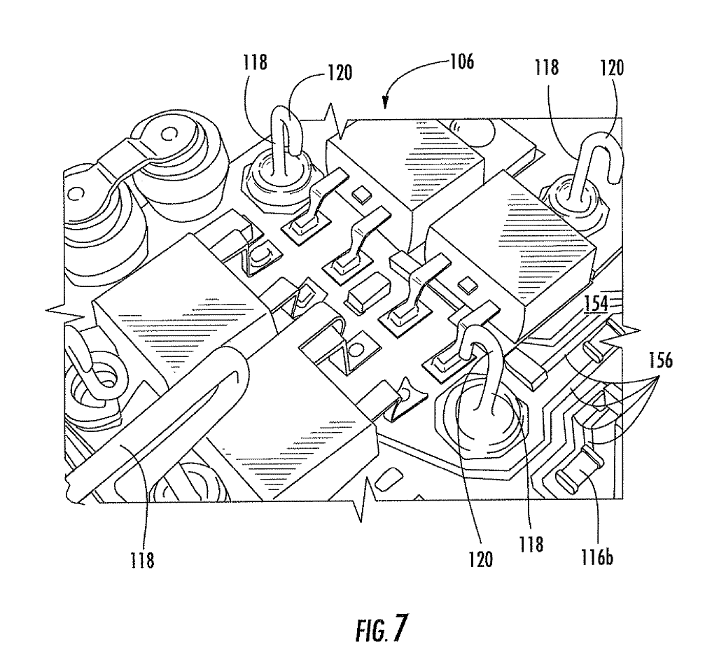

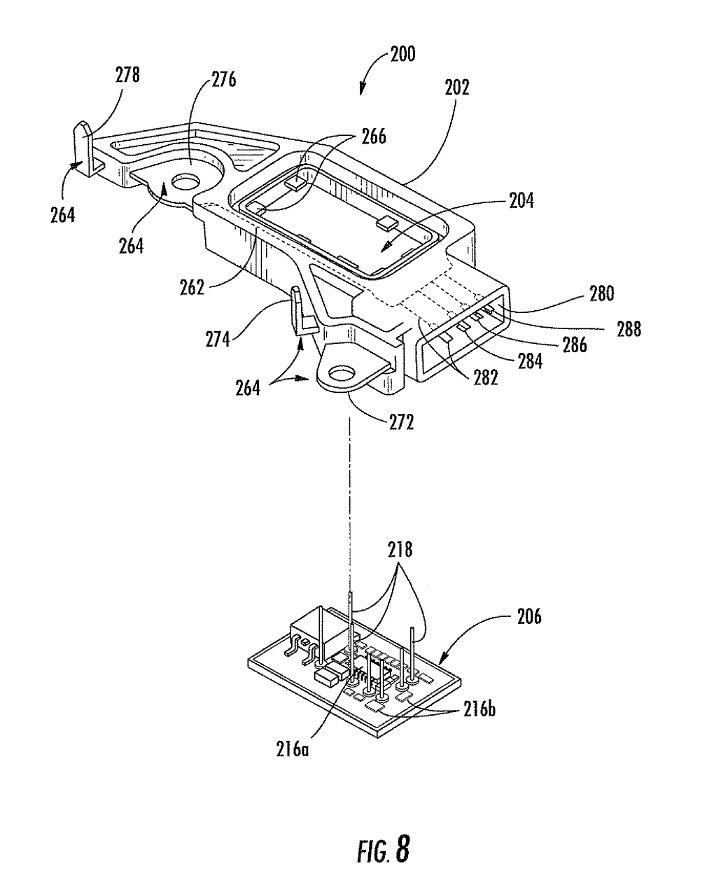

FIG. 5 is a cross-sectional view of the substrate board 106 that can be used in the present invention and showing the metallic base layer 150, insulator layer 152 on the metallic base layer 150 and a circuit layer 154 typically formed from copper on the insulator layer 152 and defining a printed circuit pattern 156 as better shown in the plan view of the substrate board in FIG. 6 and the enlarged isometric view of the substrate board shown in FIG. 7. FIG. 5 also shows in dashed lines a solder mask 158. FIGS. 6 and 7 show active components 116a, for example, transistors, and passive components 116b, for example, capacitors and resistors, which are interconnected by the printed circuit pattern 156 formed as a circuit layer 154.

The substrate board can be formed by different manufacturing techniques, and one example of a board and its manufacturing process that can be used for the present invention is disclosed in U.S. Pat. No. 4,810,563, the disclosure which is hereby incorporated by reference in its entirety. Commercially available substrate boards that can be used as boards for the present invention include substrate boards manufactured by the Bergquist Company of Minneapolis, Minn. under the tradename ThermalClad®, or a similar thermal interface substrate board manufactured by Thermagon, Inc. of Cleveland, Ohio and sold under the tradename T-Lam.

Although a metallic base layer 150 such as aluminum or copper is disclosed and preferred, it is possible in some applications that the base layer altogether could be avoided. The benefits of the substrate board 106 include the avoidance of a large heat sink and its associated mounting hardware or other thermal interface material, because the substrate board is operable to minimize solder joint fatigue and enhance heat spreading. The board has a lower operating temperature with increased power density and a reduced board size when active and passive components are mounted thereon. The number of required interconnects is reduced because surface mount technology and reflow soldering techniques are used. Automatic pick and place equipment can be used for inserting the substrate board into the board receiving cavity.

Typically, the metallic base layer 150 is formed from aluminum, but copper can also be used. For example, the metallic base layer could be about 0.040 inches (1.0 millimeter) aluminum thickness and range from about 0.020 to about 0.125 inches in thickness. The metallic base layer is typically thicker than the other layers and has a coefficient of thermal expansion such that the solder joint fatigue is minimized and heat spreading enhanced. The copper base layers can also be formed about 0.020 to about 0.125 inches thick.

The dielectric layer 152 is typically a polymer/ceramic blended material that provides electrical isolation and low thermal impedance. This layer 152 resists thermal aging and has high bond strengths and incorporates a preferred ceramic filler to enhance thermal conductivity and maintain high dielectric strength. It is a thin layer and typically about 0.003 inches, but can range in thickness from as little as 0.001 inches to about 0.012 inches depending on what isolation is required.

The circuit layer 154 is the component-mounting layer and forms a printed circuit pattern 156 that interconnects the active and passive components 116. The trace width of the printed circuit lines forming the pattern 156 can vary depending on the type of dielectric, its thickness, and base layer. The circuit layer can typically be thinly formed as a foil layer from copper. In one non-limiting example, the thickness of the circuit layer can be as little as 0.0014 inches to as much as 0.0140 inches depending on voltage regulator design and application. In another example of the invention, the copper circuit layer 154 can be about 10% of the base layer thickness or thinner. This proportion can aid in maintaining circuit flatness, especially when an aluminum base layer 150 is used. The circuit design can include various etched surfaces, including vias. Minimum circuit width of the printed circuit patterns formed as traces can be about 0.005 inches or smaller to as much as 0.015 inches or larger. An exemplary minimum space/gap for a single layer (non-plated) can be about 0.007 inches to as much as 0.030 inches. It is also possible to form the substrate board as a multilayer board. A solder mask and silk screen design can be used during production.

Different surface finishes can be available, including Hot Air Solder Leveling (HASL), which is a 63/37. pB/Sn coating. Organic Solderability Protectant (OSP) can be used a thin coating to protect copper. Flow Solderable Tin (FST) can be used. If a copper base layer is used, the soldering process during a reflow process typically should not exceed 260° C. and, if an aluminum base layer is used, should not exceed 300° C. Usually a minimum of about 0.004 inches of solder is recommended to allow a good heat transfer and withstand thermal cycling. Silver can be added and an RMA flux used.

FIGS. 1-3 show one type of connection technique using terminal connections 118, which can be formed as conductive pins with J-hook connectors 120 at the ends. It is also possible to use wire bonding as a direct attach to the board, especially if a chip on-board architecture is used.

FIGS. 6 and 7 show in detail the substrate board 106 shown in FIGS. 1-3. Different active components 116a, such as transistors, are secured to the substrate board and other passive components 116b are interconnected by the printed circuit pattern 156. The active and passive components are shown as surface mounted components that are soldered to respective traces forming the printed circuit pattern 156.

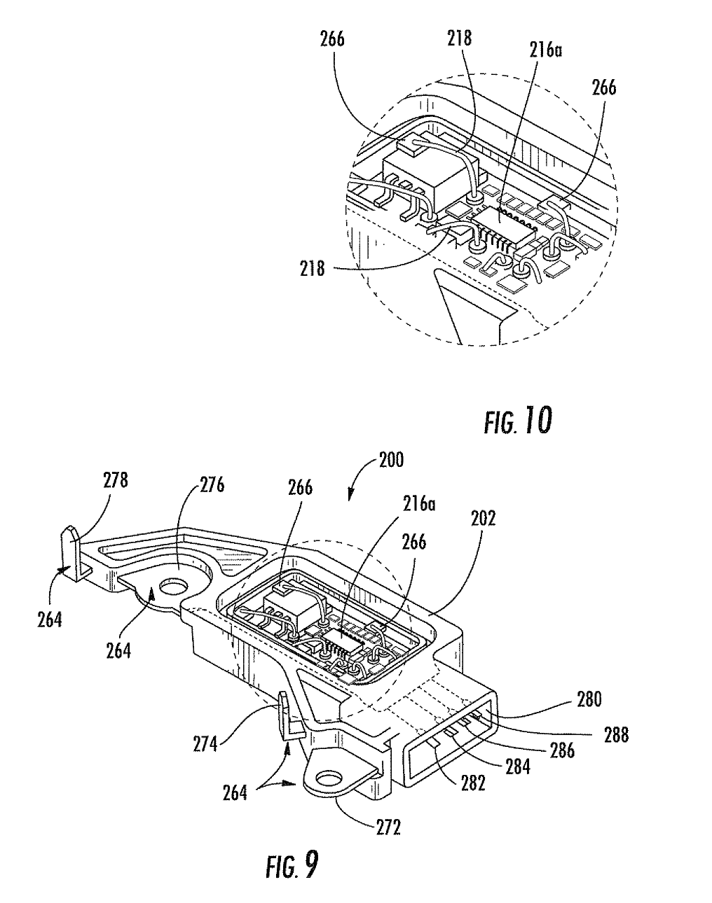

FIGS. 8-11 show a different embodiment of the voltage regulator 200 of the present invention that is used in a B-circuit (high-side) voltage regulation system for an automobile, for example, on General Motors vehicles that use CS121, CS130, and CS144 series alternators, for example, as manufactured by Delco. One example of the voltage regulator is a D411 regulator sold by Transpo Electronics, Inc. For purposes of description, similar functional elements as described relative to the voltage regulator embodiment shown in FIGS. 1-7 are referenced with numerals beginning in the 200 series.

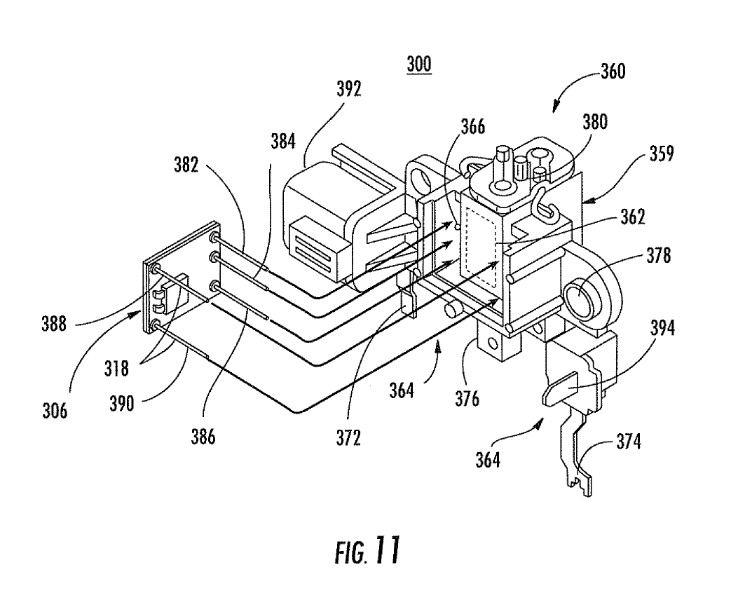

In this particular embodiment, the voltage regulator body 202 includes a lead frame assembly 260 formed from an insulator material with embedded conductors 262 forming a lead frame shown by dashed lines within the lead frame assembly. The lead frame 262 includes external lead frame terminals 264 that connect to wires and terminals of various devices controlled by the voltage regulator, or receive signals from other devices. The board receiving cavity 204 is an open cavity as illustrated and the embedded conductors 262 within the lead frame assembly 260 include internal terminals 266 that connect to the terminal connections 218 formed as conductive pins extending from the substrate board 206, which are bent and soldered onto the internal terminals 266 as shown in FIGS. 9 and 10. The substrate board includes active components 216a, for example, an IC or transistor, and passive components 216b, for example, resistors.

FIG. 8 shows that the substrate board 206 is received into the board receiving cavity 204 from underneath. A cavity cover (not shown) can be placed over the cavity after the substrate board is inserted therein. Two opposing cavity covers could be used on one and the other side filled with insulative material. Silicon gel can be used as a fill, or even epoxy or urethane. The different external lead frame terminals 264 include a ground connection 272, a field connection 274, a battery (B+) connection 276 that acts as a B+ terminal and a stator connection 278. The lead frame assembly can receive a wiring harness connector within a wiring slot 280 and includes a sense connector 282 for B+, an ignition connector 284, a light connector 286 and a stator or shorted stator connector 288 as shown by the dashed lines.

During assembly, when the substrate board 206 is received into the board receiving cavity 204, all conductive pins 218 should be bent inward so that they do not interfere with the embedded conductors forming the internal terminals 266. The silicon gel or conductive epoxy or other adhesive can be used to secure the substrate board 206 and later a cavity cover. The conductive pins are bent and soldered to the internal terminals and the board receiving cavity 204 is filled with a silicon gel. The cavity cover is then placed over the cavity and secured using epoxy.

The illustrated voltage regulator 200 is predominantly used with a CS-series voltage regulator, for example, with a CS130 series alternator. The voltage regulator circuit could incorporate a field effect transistor having a drain terminal connected to B+ and to an integrated circuit chip, for example, its terminal A. An external sense connector could be connected to terminal 3 of the IC chip, which typically has dual sensing ability, either external or internal. This voltage regulator 200 is a B-circuit as a high-side drive with a voltage set point at about 14.7 volts. This voltage regulator can be light activated and the stator input can turn off the light. It preferably has a soft start feature.

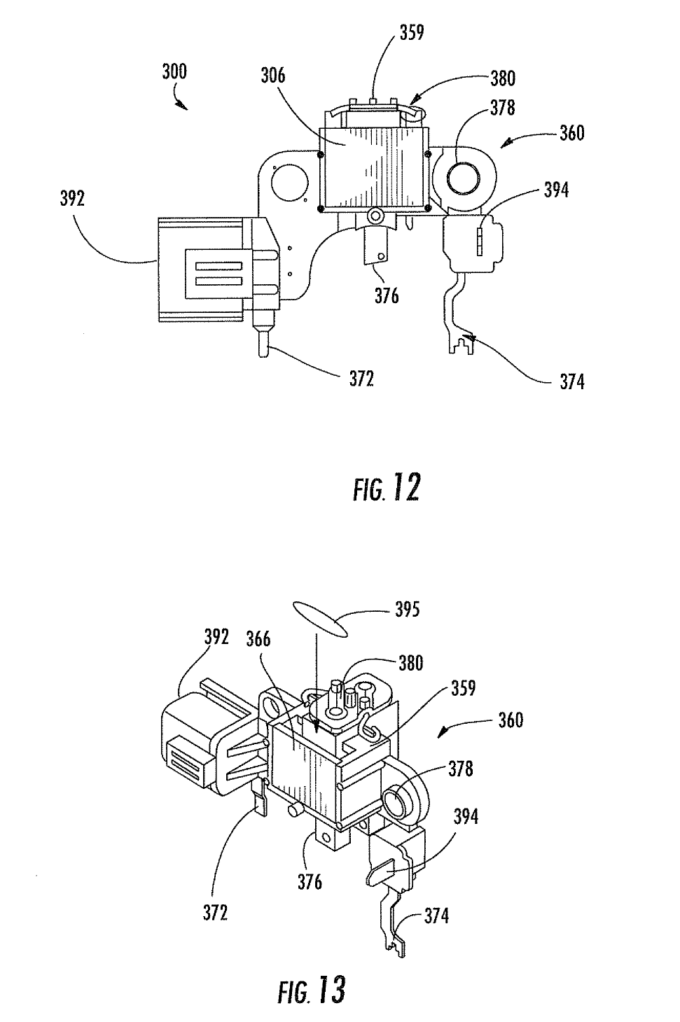

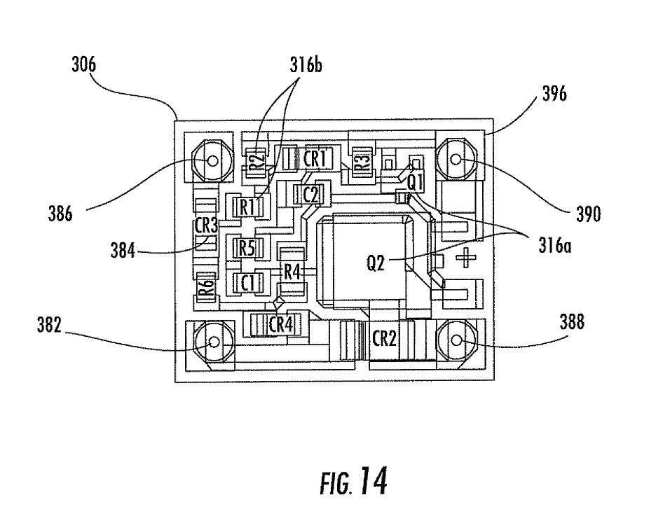

FIGS. 11-14 illustrate another embodiment of the voltage regulator of the present invention used in an A-circuit (low-side) regulation for Mitsubishi voltage regulators, for example, as used on Ford Tracer, Probe and Mazda and similar vehicles. Functional elements in this embodiment, which are similar to functional elements with respect to the first embodiment of FIGS. 1-7 and the second embodiment of FIGS. 8-10, are explained with reference to the 300 series.

The A-circuit voltage regulation in this example would typically include a slip-on brush-ring of about 26 millimeter ID. The voltage regulator 300 includes a voltage regulator body 302 that includes a lead frame assembly 360 formed from an insulator material using embedded conductors 362 include external lead frame terminals 364 and internal terminals 366 (shown by dashed lines) to be connected to terminal connections 318 as conductive pins on the substrate board 306 as shown in FIG. 11.

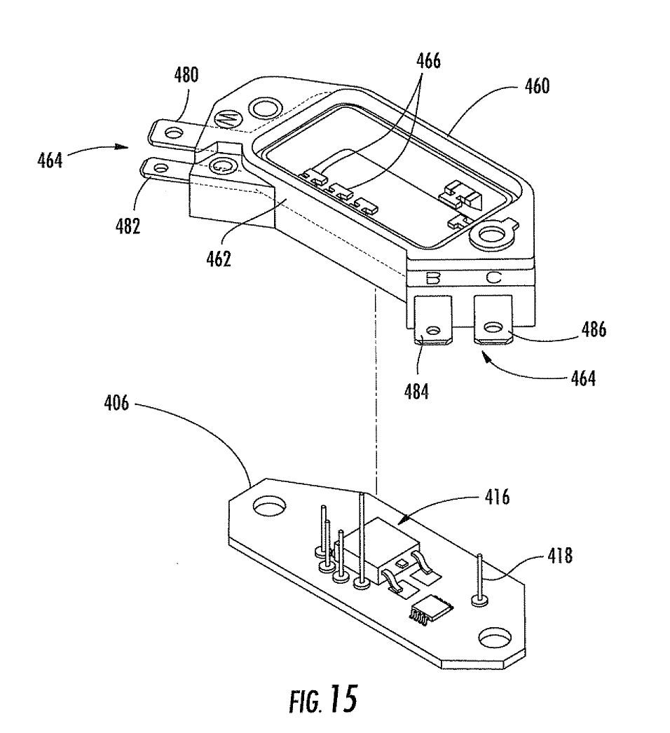

The terminal connections 318 formed as conductive pins are received within pin receiving slots 359a of a brush holder 359 formed as part of the lead frame assembly 360. The internal terminals 366 from the lead frame assembly 360 connect to the conductive pins 318. The lead frame assembly 360 includes the external lead frame terminals 364 to form a B+ trio terminal 372, a stator terminal 374, and an “F” or bottom brush terminal 376 and can include a ring assembly (not shown). This type of voltage regulator for Mitsubishi is sold as one example under the designation IM265 by Transpo Electronics, Inc. and has a system voltage of 12 volts and is used on the “A” circuit or low side drive with a trio excitation. It is indicator light activated, and in one example, is a 28 millimeter brush ring and has an operating temperature range of about −40° C. to about 125° C. It has a field current of about 4 amps and a voltage set point at 4,000 rpm of about 14.5 volts. It includes a B− terminal 378 and can include a field terminal 380 at the top. The pins as terminal connections from the substrate board include a sense pin 382, light pin 384, and trio pin 386 on one side, and a field pin 388 and ground pin 390 on the other side and as shown in the plan view of the substrate board in FIG. 14. A S-L connection 392 is at the side and includes a B+ sense connection as the S and the B+ trio as the L connection. A stator end connection 394 can be N/C shorted to a stator end and stator out as a P connector also.

The conductive pins are typically inserted through the brush holder 359 as part of the lead frame assembly and are bent and soldered. Epoxy or other adhesive 395 can be added into the opening between the substrate board and the brush holder 359 as part of the lead frame assembly to fill the entire cavity during assembly.

FIG. 14 shows a plan view of the substrate board with a solder mask 396 in outline and the ground, field, trio, sense and light conductive pins and their base supports used to support the conductive pins on the substrate board. Two transistors Q1 and Q2 are illustrated as active components 316a that are positioned on the substrate board and connected by the printed circuit pattern and connected to various passive components 316b, including resistors and capacitors.

It is also possible that the substrate board and manufacturing techniques with regard to the voltage regulators could be used for some ignition modules. FIG. 15 is an ignition module similar in construction to the voltage regulator embodiment shown in FIGS. 8-10. Reference numerals begin in the 400 series. A lead frame assembly 460 is formed of an insulator material and has embedded conductors 462 shown by the dashed lines and includes external lead frame terminals 464 and internal terminals 466 that connect to the terminal connections formed as conductive pins 418 of the substrate board 406 within the board receiving cavity 404. Conductive pins 418 interconnect through a circuit pattern active and passive components 416. This type of ignition module is used with a magnetic pick-up system that is dwell controlled by a module with transient protection on all pins. One example of this type of ignition module is sold under the designation DM1906 by Transpo Electronics, Inc. P+ and P− terminals 480,482 are positioned on one side and a B+ and a coil terminal 484,486 on the other as illustrated. P+ and P− are also termed work (W) and ground (G) terminals. The lead frame assembly 460 and substrate board 406 include fastener receiving holes, as illustrated. The cavity cover can be placed over the cavity and the manufacturing and filling of the cavity occur as described with the embodiments of voltage regulators as described before. Active and passive components 416 form a circuit for an ignition module 400 used in a vehicle.

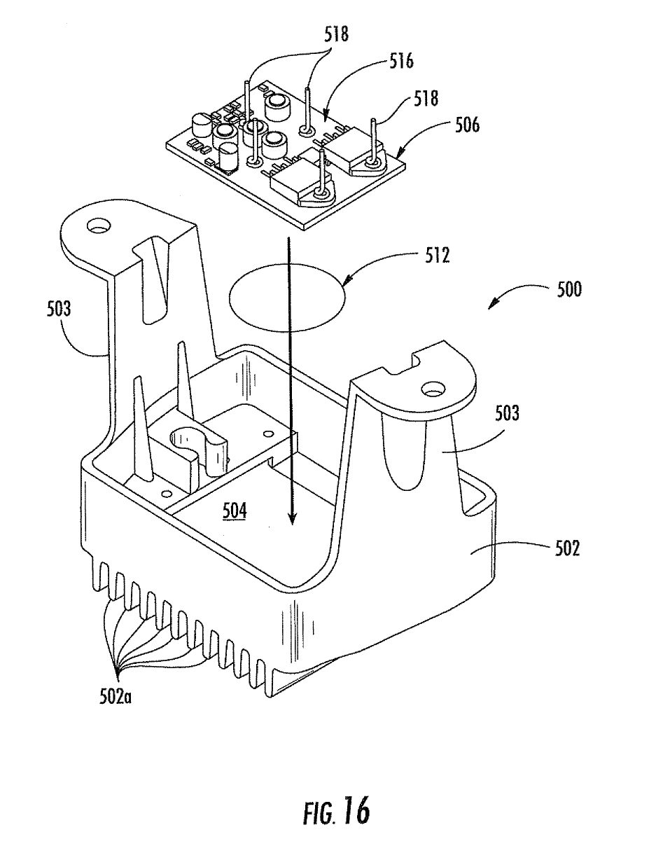

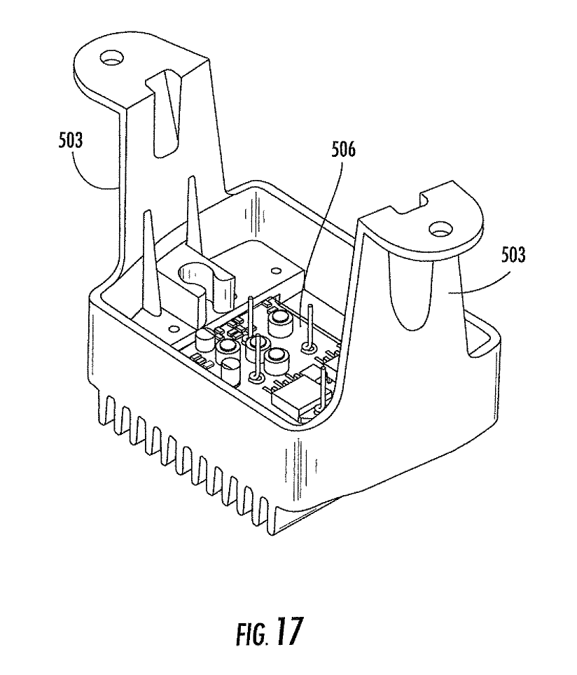

FIG. 16 shows another embodiment of the voltage regulator 500 used for a motorcycle, such as Harley-Davidson motorcycles, and sold under the designation H1988 by Transpo Electronics, Inc., as one non-limiting example. Reference numerals begin in the 500 series. The voltage regulator 500 includes an integrally formed metallic body member forming a housing 502 and includes support legs 503 that permit the voltage regulator to be attached by bolts or other fasteners to the frame of the motorcycle, for example, on the front of the motorcycle frame. The housing 502 includes cooling fins 502a on an outer surface. The substrate board 506 includes the active and passive components 516 and is secured by an adhesive 512 inside the cavity 504 as illustrated. Wires as part of a wiring harness would connect to the conductive pins 518 for a long lead length to motorcycle components. The cavity 504 would be filled and manufacturing steps would be similar as described before. The regulator 500 can be bolted on a motorcycle frame and can be designed depending on the type of motorcycle models to be regulated and can range from 15 amp operation up to 32 amp operation.

FIG. 17 shows the substrate board 506 received within the board receiving cavity 504 as formed within the housing 502 or “can” as known to those skilled in the art.

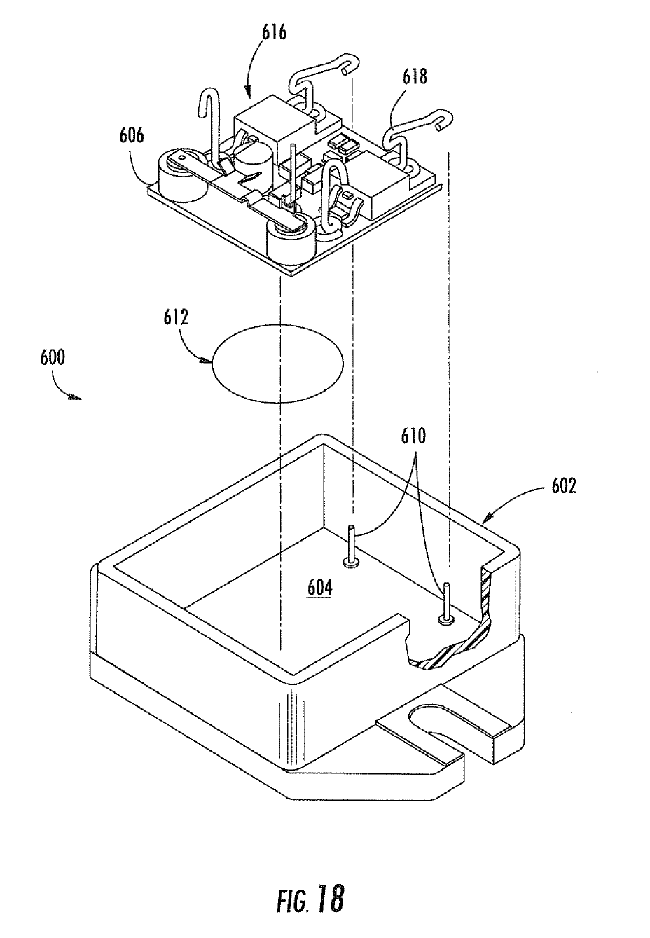

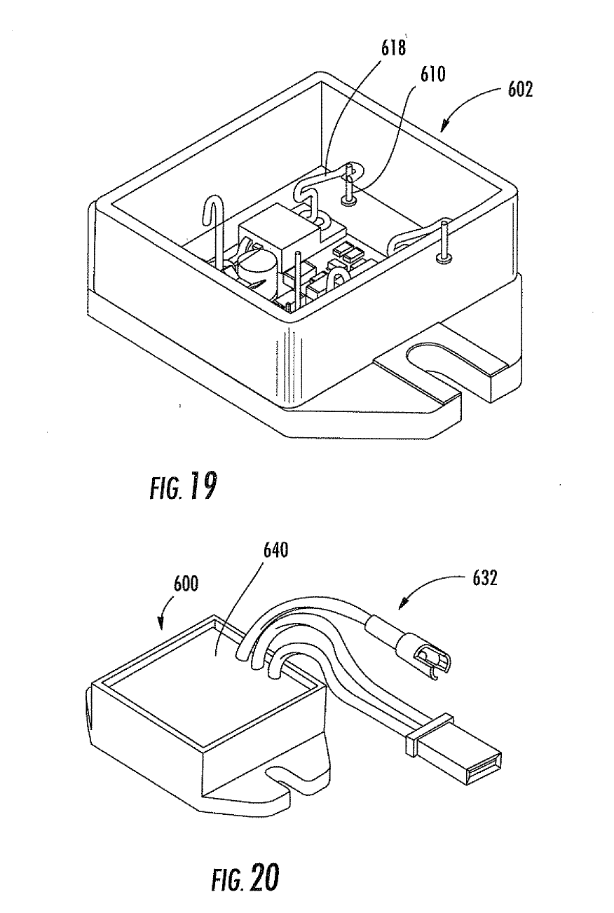

FIGS. 18-20 illustrate another embodiment of the voltage regulator 600 of the present invention. Reference numerals begin in the 600 series. This regulator 600 can be used with permanent magnet systems, for example, Briggs and Stratton small horsepower engines, in which the voltage regulator body 602 is formed as an integrally formed metallic body member forming a housing 602 or “can” and includes the board receiving cavity 604. Larger engines could be used also. An adhesive 612 attaches the substrate board 606 inside the cavity 604, which includes two ground pins 610 as in the embodiment of FIGS. 1-7. The substrate board 606 includes active and passive components 616, and the conductive pins 618 with J-connectors 620, which connect ends of wires 626 in a crimped manner and soldered.

FIG. 20 shows how the conductive pins 618 forming the terminal connections receive wires 626 as part of a wiring harness 632 as in the embodiment described relative to FIGS. 1-7. The integrally formed metallic body member forms the “can” 602 as known to those skilled in the art. This type of voltage regulator can be used with a series-type regulation, as one non-limiting example, and can be used on 10-16 amp charging systems for 8-20 horsepower engines and is sold by Transpo Electronics, Inc. under part no. BR4890 as one non-limiting example. Other examples include lawn and garden, marine, motorcycle, and personal watercraft (jet ski) applications. FIG. 20 shows how a filler 640, for example, urethane or epoxy, is used to secure the wiring harness 632 and cover the substrate board and the active and passive components.

The present invention is advantageous and provides an enhanced voltage regulator used for automobile, motorcycle and marine applications in which the substrate board is secured to the voltage regulator body and receives the active and passive voltage regulator components to provide enhanced voltage regulator operation and advanced design that can withstand heat and provide greater thermal conductivity as described above.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

1-37. (canceled)

38. A method of forming a voltage regulator, which comprises:
mounting on a voltage regulator body a substrate board, which comprises a metallic base layer, an insulator layer on the metallic base layer, and a circuit layer on the insulator layer and defining a printed circuit pattern, and including active and passive voltage regulator components mounted on the substrate board and interconnected to each other by the printed circuit pattern to form a voltage regulating circuit; and
interconnecting terminal connections that are secured to the substrate board and operatively connected to selected active and passive components or printed circuit pattern and extend from the substrate board to connectors carried by the voltage regulator body and adapted to be connected to devices controlled by the voltage regulator.

39. A method according to claim 38, which further comprises inserting the substrate board within a board receiving cavity of the voltage regulator body.

40. A method according to claim 39, which further comprises filling the board receiving cavity with an insulator material to cover the substrate board and any active and passive components.

41. A method according to claim 38, which further comprises forming the voltage regulator body as an integrally formed metallic housing.

42. A method according to claim 38, which further comprises forming the voltage regulator body to include a lead frame assembly formed from insulator material that includes embedded conductors for connecting to terminal connections.

43. A method according to claim 42, which further comprises forming the terminal connections as conductive pins and connecting the conductive pins to embedded conductors within the lead frame assembly.

44. A method according to claim 38, which further comprises surface mounting the active and passive voltage regulator components on the substrate board.

45. A method according to claim 38, which further comprises reflow soldering active and passive voltage regulator components on the substrate board.

46. A method according to claim 38, which further comprises forming the metallic base layer of the substrate board from copper or aluminum.

47. A method of forming a voltage regulator, which comprises:
forming a substrate board having an aluminum base layer, an insulator layer on the aluminum base layer, and a circuit layer on the insulator layer and defining a printed circuit pattern;
soldering active and passive voltage regulator components on the substrate board and interconnected to each other by the printed circuit pattern to form a voltage regulating circuit such that the coefficient of thermal expansion for the aluminum base layer minimizes solder joint fatigue and enhances heat spreading; and
applying the substrate board onto a voltage regulator body.

48. A method according to claim 47, which further comprises forming the aluminum base layer having a thickness of about 0.020 to about 0.125 inches.

49. A method according to claim 37, which comprises interconnecting terminal connections secured to the substrate board to connectors carried by the voltage regulator body that are adapted to be connected to devices controlled by the voltage regulator.

50. A method according to claim 47, which further comprises inserting the substrate board within a board receiving cavity of the voltage regulator body.

51. A method according to claim 50, which further comprises filling the board receiving cavity with an insulator material to cover the substrate board and any active and passive components.

52. A method according to claim 47, which further comprises forming the voltage regulator body as an integrally formed metallic housing.

53. A method according to claim 47, which further comprises forming the voltage regulator body to include a lead frame assembly formed from insulator material that includes embedded conductors that connect to terminal connections.

54. A method according to claim 47, which further comprises surface mounting the active and passive voltage regulator components on the substrate board.

55. A method according to claim 47, which further comprises reflow soldering active and passive voltage regulator components on the substrate board.
